(19) United States
(12) Patent Application Publication
(10) Pub. No.: US 2017/0069820 A1
(43) Pub. Date: Mar. 9, 2017

(54) PIEZOELECTRIC DEVICE AND METHOD OF MANUFACTURING PIEZOELECTRIC DEVICE

(71) Applicant: Murata Manufacturing Co., Ltd., Nagaokakyo-shi (JP)

(72) Inventors: Takuo Hada, Nagaokakyo-shi (JP); Kansho Yamamoto, Nagaokakyo-shi (JP)

(21) Appl. No.: 15/355,657

(22) Filed: Nov. 18, 2016

Related U.S. Application Data
(63) Continuation of application No. PCT/JP2015/066453, filed on Jun. 8, 2015.

(30) Foreign Application Priority Data
Jun. 13, 2014 (JP) 2014-122545

(51) Int. Cl. H01L 41/047; H01L 41/29; H01L 41/053

(52) U.S. Cl. CPC H01L 41/047; H01L 41/053; H01L 41/29

(57) ABSTRACT

A piezoelectric device that includes a support layer, a lower electrode, a piezoelectric film and an upper electrode on a substrate. In the substrate, a first opening is provided that penetrates through at least part of the substrate in a thickness direction of the substrate. A second opening that faces the support layer and the first opening is provided above the first opening. An opening area of the first opening is smaller than an opening area of the second opening.

### CROSS REFERENCE TO RELATED APPLICATIONS

The present application is a continuation of International application No. PCT/JP2015/066453, filed Jun. 8, 2015, which claims priority to Japanese Patent Application No. 2014-122545, filed Jun. 13, 2014, the entire contents of each of which are incorporated herein by reference.

### FIELD OF THE INVENTION

The present invention relates to a piezoelectric device and to a method of manufacturing a piezoelectric device.

### BACKGROUND OF THE INVENTION

In the related art, a piezoelectric device is known that has a membrane part in order to improve the characteristics of the piezoelectric device. The membrane part is formed of a combination of a piezoelectric layer that is located above a space such as a concavity or an opening formed in a substrate and two electrodes that sandwich the piezoelectric layer therebetween.

For example, Patent Document 1 discloses the following method of manufacturing a piezoelectric device (refer to paragraphs [0034] to [0042] of Patent Document 1). First, a passivation layer is formed on a front surface of a substrate. Next, an opening that penetrates through the substrate and reaches the passivation layer is formed by subjecting part of a rear surface of the substrate to dry etching. Next, manufacture of a piezoelectric device having a membrane part is completed by sequentially stacking a first conductive layer, a piezoelectric layer and a second conductive layer on the passivation layer.

In addition, Patent Document 2 discloses the following method of manufacturing a piezoelectric device (refer to paragraphs [0029] to [0040] of Patent Document 2). First, a buried oxide (BOX) layer composed of an insulator and a silicon layer composed of single crystal silicon are stacked in this order on a silicon substrate. Next, a trench is formed in the silicon layer at a prescribed position and a buried oxide film is formed in the trench. Next, a lower electrode, a piezoelectric film and an upper electrode are sequentially formed on the silicon layer and an opening is formed in the silicon substrate by removing a part of the silicon substrate from a prescribed region from the rear surface of the silicon substrate up to the BOX layer by using a deep RIE method. Finally, manufacture of a piezoelectric device having a membrane part is completed by removing the BOX layer and the buried oxide film exposed at the bottom of the opening by performing reactive ion etching (RIE) using a fluorine-containing gas or etching using a buffered hydrofluoric acid (BHF) solution.
Patent Document 1: U.S. Patent Application Publication No. 2011/0198970
Patent Document 2: Japanese Unexamined Patent Application Publication No. 2010-118730

### SUMMARY OF THE INVENTION

However, in the methods of manufacturing a piezoelectric device described in Patent Document 1 and Patent Document 2, it has not been possible to achieve high processing accuracy when forming the opening using drying etching (including variations in the shape and dimensions of the opening and variations within the plane of the wafer). In particular, in piezoelectric devices used in ultrasonic transducers, microphones and so forth, the piezoelectric device operates by the membrane part undergoing out-of-plane vibration, and therefore the shape and dimensions of the opening (shape and dimensions of membrane part) affect the vibration of the membrane part (particularly the frequency). Therefore, there is a problem with piezoelectric devices manufactured using the manufacturing methods described in Patent Document 1 and Patent Document 2 in that there are large variations in the characteristics (particularly the frequency characteristics) of the piezoelectric devices.

In light of the above-described circumstances, an object of the present invention is to provide a piezoelectric device that can suppress variations in the characteristics thereof and to provide a method of manufacturing the piezoelectric device.

A piezoelectric device according to the present invention includes a substrate; a support layer on the substrate; a lower electrode on the support layer; a piezoelectric film on the lower electrode; and an upper electrode on the piezoelectric film. In the substrate, a first opening is provided that penetrates through at least part of the substrate in a thickness direction of the substrate, a second opening that faces the support layer and the first opening is provided above the first opening, and an opening area of the first opening is smaller than an opening area of the second opening.

In the piezoelectric device according to the present invention, the second opening may be provided so as to contain the first opening in a plan view of the piezoelectric device.

In the piezoelectric device according to the present invention, the second opening may be provided in at least either of the substrate and the support layer.

The piezoelectric device according to the present invention may further include an insulating layer that is disposed between the substrate and the support layer.

In the piezoelectric device according to the present invention, the second opening may be provided in the insulating layer.

A method of manufacturing a piezoelectric device according to the present invention includes: forming a sacrificial layer at least one of on or below a surface of a substrate; forming a support layer on the sacrificial layer; forming a lower electrode on the support layer; forming a piezoelectric film on the lower electrode; forming an upper electrode on the piezoelectric film; forming a second opening by removing the sacrificial layer; and forming a first opening that penetrates through at least part of the substrate in a thickness direction of the substrate by removing at least part of the substrate in the thickness direction of the substrate. The forming of the first opening is performed such that an opening area of the first opening is smaller than an opening area of the second opening.

The method of manufacturing a piezoelectric device according to the present invention may further include, prior to forming the second opening, forming a through hole that penetrates through at least the piezoelectric film and the lower electrode in thickness directions thereof and extends to the sacrificial layer.

In the method of manufacturing a piezoelectric device according to the present invention, the forming of the first opening can be performed prior to the forming of the second opening, and the forming of the first opening can be performed such that a surface of the sacrificial layer is exposed in the first opening.

The method of manufacturing a piezoelectric device according to the present invention may further include, prior to the forming of the sacrificial layer, forming an insulating layer on the substrate.

In the method of manufacturing a piezoelectric device according to the present invention, the forming of the sacrificial layer may be performed such that the sacrificial layer is formed at least one of on or below a surface of the insulating layer.

According to the present invention, a piezoelectric device and a method of manufacturing the piezoelectric device are provided that can suppress variations in the characteristics of the piezoelectric device.

### BRIEF DESCRIPTION OF THE DRAWINGS

FIG. 1(a) is a schematic sectional view of a piezoelectric device of embodiment 1 and FIG. 1(b) is a schematic plan view in which the piezoelectric device of embodiment 1 illustrated in FIG. 1(a) is viewed from directly above.

FIG. 2(a) is a schematic sectional view depicting part of a manufacturing step in an example of a method of manufacturing the piezoelectric device of embodiment 1 and FIG. 2(b) is a schematic plan view in which the content of FIG. 2(a) is viewed from directly above.

FIG. 3(a) is a schematic sectional view of part of a manufacturing step in the example of a method of manufacturing the piezoelectric device of embodiment 1 and FIG. 3(b) is a schematic plan view in which the content of FIG. 3(a) is viewed from directly above.

FIG. 4(a) is a schematic sectional view of part of a manufacturing step in the example of a method of manufacturing the piezoelectric device of embodiment 1 and FIG. 4(b) is a schematic plan view in which the content of FIG. 4(a) is viewed from directly above.

FIG. 5(a) is a schematic sectional view of part of a manufacturing step in the example of a method of manufacturing the piezoelectric device of embodiment 1 and FIG. 5(b) is a schematic plan view in which the content of FIG. 5(a) is viewed from directly above.

FIGS. 6(a) to 6(e) are schematic sectional views of a method of manufacturing a piezoelectric device of embodiment 2.

FIGS. 7(a) to 7(e) are schematic sectional views of a method of manufacturing a piezoelectric device of embodiment 3.

FIGS. 8(a) to 8(e) are schematic sectional views of a method of manufacturing a piezoelectric device of embodiment 4.

FIGS. 9(a) to 9(d) are schematic sectional views of a method of manufacturing a piezoelectric device of embodiment 5.

FIGS. 10(a) to 10(e) are schematic sectional views of a method of manufacturing a piezoelectric device of embodiment 6.

FIGS. 11(a) to 11(d) are schematic sectional views of a method of manufacturing a piezoelectric device of embodiment 7.

FIG. 12 (a) to 12 (e) are schematic sectional views of a method of manufacturing a piezoelectric device of embodiment 8.

### DETAILED DESCRIPTION OF THE PREFERRED EMBODIMENTS

Hereafter, embodiments will be described as examples of the present invention. In the drawings used in the description of the embodiments, the same reference symbols denote identical or equivalent parts.

### Embodiment 1

### Structure of Piezoelectric Device

FIG. 1(a) illustrates a schematic sectional view of a piezoelectric device of embodiment 1. In addition, FIG. 1(b) illustrates a schematic plan view in which the piezoelectric device of embodiment 1 illustrated in FIG. 1(a) is viewed from directly above.

As illustrated in FIG. 1(a), the piezoelectric device of embodiment 1 includes a substrate 11, an insulating layer 12 that is provided on the substrate 11, a support layer 14 that is provided on the insulating layer 12, a lower electrode 15 that is provided on the support layer 14, a piezoelectric film 16 that is provided on the lower electrode 15 and an upper electrode 17 that is provided on the piezoelectric film 16.

In addition, a first opening 23 that penetrates through the substrate 11 in a thickness direction of the substrate 11 is provided in the piezoelectric device of embodiment 1. A second opening 22 that faces the support layer 14 and the first opening 23 is provided above the first opening 23. A through hole 21 that penetrates through the piezoelectric film 16, the lower electrode 15 and the support layer 14 in the thickness directions thereof and extends to the second opening 22 is provided in the piezoelectric device of embodiment 1.

Here, the first opening 23 is provided in the substrate 11, whereas the second opening 22 is provided in the support layer 14 and the insulating layer 12.

In addition, as illustrated in FIGS. 1(a) and 1(b), a diameter a of the first opening 23 is smaller than a diameter b of the second opening 22 in the piezoelectric device of embodiment 1. Consequently, an opening area of the first opening 23 is smaller than an opening area of the second opening 22. In addition, as illustrated in the plan view of FIG. 1(b), the second opening 22 is provided so as to contain the first opening 23.

<Method of Manufacturing Piezoelectric Device>

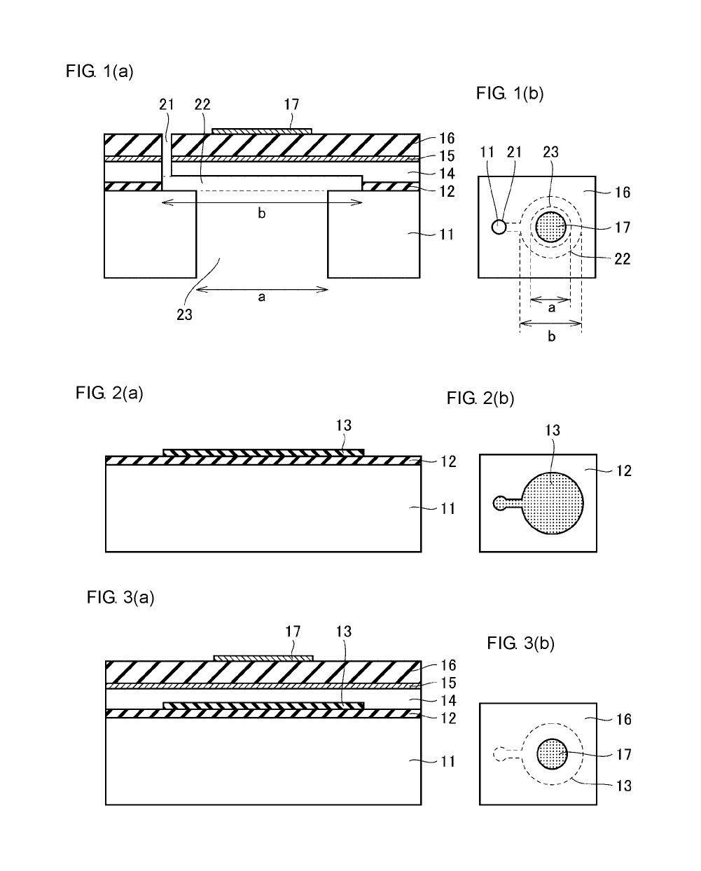

Hereafter, an example of a method of manufacturing the piezoelectric device of embodiment 1 will be described while referring to FIGS. 2 to 5. First, the insulating layer 12 is formed on a surface of the substrate 11 as illustrated in the schematic sectional view of FIG. 2(a) and the schematic plan view of FIG. 2(b). Here, a silicon (Si) substrate having a thickness of around 600 μm is used as the substrate 11, for example. In addition, a silicon oxide (SiO₂) film formed using a thermal oxidation method and having a thickness of around 1.5 μm can be formed as the insulating layer 12, for example.

Next, a sacrificial layer 13 is formed on the insulating layer 12 as illustrated in FIGS. 2(a) and 2(b). Here, as the sacrificial layer 13, a titanium (Ti) film having a thickness of around 20 nm to 1 μm can be formed in the shape of a desired membrane part by using a sputtering method, for example. Rather than a Ti film, a film composed of any of a variety of metals, alloys or oxides such as an aluminum (Al) film or a SiO₂ film can be formed as the sacrificial layer 13, for example.

Next, the support layer 14 is formed on the insulating layer 12 so as to cover the entirety of the sacrificial layer 13, as illustrated in the schematic sectional view of FIG. 3(a) and the schematic plan view of FIG. 3(b). Here, as the support layer 14, an aluminum nitride (AlN) film can be formed using a sputtering method, for example.

Next, the lower electrode 15 is formed on the support layer 14, as illustrated in FIGS. 3(a) and 3(b). Here, as the lower electrode 15, a molybdenum (Mo) film can be formed using a sputtering method, for example.

Next, the piezoelectric film 16 is formed on the lower electrode 15, as illustrated in FIGS. 3(a) and 3(b). Here, as the piezoelectric film 16, an AlN film can be formed using a sputtering method for example, but, rather than an AlN film, a film composed of lead zirconate titanate (PZT), potassium sodium niobate (KNN) or zinc oxide (ZnO) can be formed instead, for example.

Next, the upper electrode 17 is formed on the piezoelectric film 16, as illustrated in FIGS. 3(a) and 3(b). Here, as the upper electrode 17, an Al film or a Mo film can be formed using a sputtering method, for example.

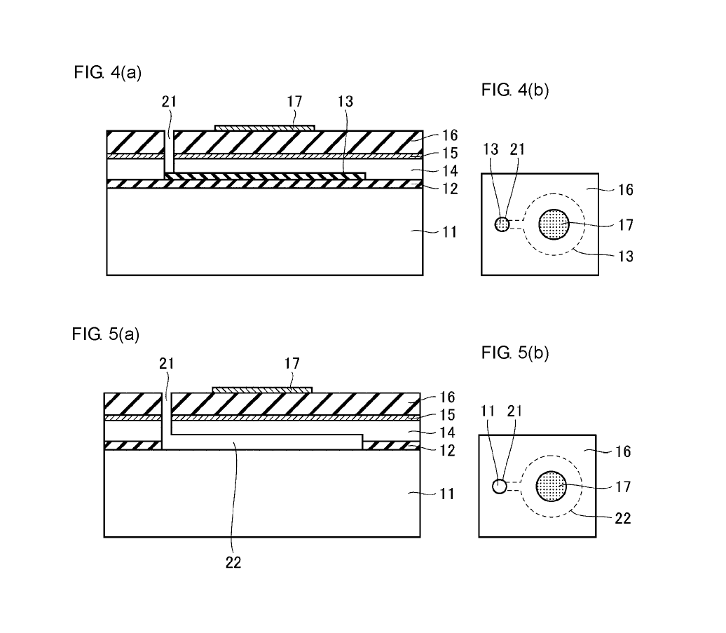

Next, the through hole 21 is formed as illustrated in the schematic sectional view of FIG. 4(a) and the schematic plan view of FIG. 4(b). Here, the through hole 21 can be formed by removing material from the piezoelectric film 16 and the lower electrode 15 in the form of a cylinder having an opening with a diameter of around 10 μm, for example, so that the through hole 21 penetrates through the piezoelectric film 16 and the lower electrode 15 in the thickness directions thereof and reaches the sacrificial layer 13. The method of forming the through hole 21 is not especially limited and dry etching or wet etching can be used, for example.

Next, the sacrificial layer 13 is removed by wet etching by guiding an etching liquid to the sacrificial layer 13 via the through hole 21, as illustrated in the schematic sectional view of FIG. 5(a) and the schematic plan view of FIG. 5(b). Thus, the second opening 22, which is a space between the support layer 14 and the substrate 11, is formed.

After that, as illustrated in FIG. 1(a), the first opening 23 is formed in the substrate 11. Here, the first opening 23 can be formed by removing material from the substrate 11 by performing dry etching from the rear surface side (side opposite side where insulating layer 12 is formed) of the substrate 11 until reaching the second opening 22, for example.

The piezoelectric device of embodiment 1 can be manufactured as described above. The membrane part of the piezoelectric device of embodiment 1 is a part having a multilayer structure made up of the parts of the lower electrode 15, the piezoelectric film 16 and the upper electrode 17 that are located above the second opening 22.

<Operational Effect>

In Embodiment 1, the shape and dimensions of the membrane part can be determined by the shape and dimensions of the sacrificial layer 13. Therefore, in embodiment 1, it is possible to achieve higher processing accuracy in determining the shape and dimensions of the membrane part compared with Patent Document 1 and Patent Document 2 in which the membrane part is formed by providing an opening in the substrate through dry etching. Therefore, in embodiment 1, variations in the characteristics of the piezoelectric device (particularly the frequency characteristics) can be reduced compared with Patent Document 1 and Patent Document 2.

In other words, since the sacrificial layer 13 is much thinner than the substrate 11, variations in the shape and dimensions of the sacrificial layer 13 of embodiment 1 can be greatly suppressed compared with variations in the shape and the dimensions of the opening formed by dry etching the substrate from the rear surface side as in Patent Document 1 and Patent Document 2. In embodiment 1, the shape and dimensions of the membrane part are determined by the shape and dimensions of the sacrificial layer 13 and therefore variations in the characteristics of the piezoelectric device (particularly the frequency characteristics) can also be suppressed.

Furthermore, in embodiment 1, the volume of the space below the membrane part is increased by the second opening 22, which is formed by removing the sacrificial layer 13, and the first opening 23, which is formed by removing part of the substrate 11, and therefore it is unlikely that the elasticity of a sound propagating medium such as the air in the space will hinder vibration (particularly the amplitude) of the membrane part. Consequently, in embodiment 1, the characteristics of the piezoelectric device (particularly the amplitude characteristics, and the sound pressure in the case of an ultrasonic transducer) can be improved.

As described above, in embodiment 1, variations in the characteristics of the piezoelectric device can be reduced by determining the shape and dimensions of the membrane part by using the sacrificial layer 13, which has a sufficiently smaller thickness than the substrate 11. Furthermore, as a result of the first opening 23, which has a smaller opening area than the second opening 22, being provided below the second opening 22, the first opening 23 does not affect the shape and the dimensions of the membrane part, which are determined by the second opening 22, and the volume of the space below the membrane part can be increased. As described above, in embodiment 1, a piezoelectric device can be provided that realizes improved characteristics and can reduce variations in the characteristics thereof.

Other than the materials described above, films containing one or two or more materials selected from a group composed of for example platinum (Pt), gold (Au), Al, titanium (Ti), nickel chromium (NiCr), tungsten (W), ruthenium (Ru) and chromium (Cr) can also be formed as the lower electrode 15 and the upper electrode 17 described above.

Furthermore, although at least either of the lower electrode 15 and the upper electrode 17 can be formed over the through hole 21 in the above description, it is preferable that the lower electrode 15 and the upper electrode 17 be not formed over the through hole 21.

### Embodiment 2

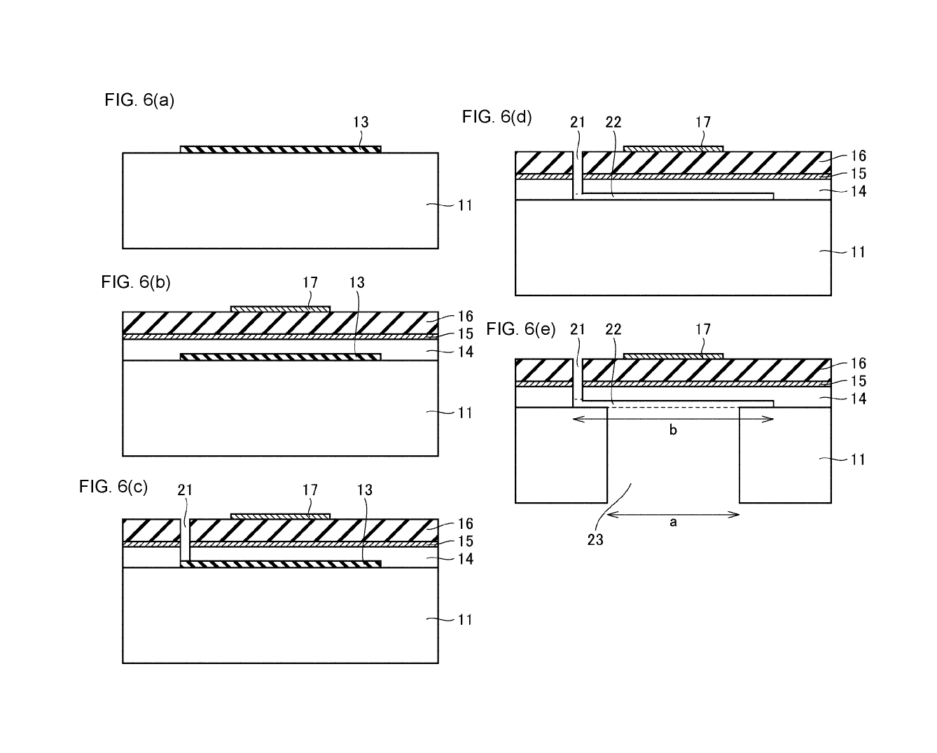

Embodiment 2 is characterized in that a piezoelectric device is manufactured by forming the sacrificial layer 13 directly on the substrate 11 without forming the insulating layer 12. Hereafter, a method of manufacturing the piezoelectric device of embodiment 2 will be described while referring to the schematic sectional views of FIGS. 6(a) to 6(e).

First, the sacrificial layer 13 is formed on the substrate 11 as illustrated in FIG. 6(a). Next, as illustrated in FIG. 6(b), the support layer 14 is formed on the substrate 11 so as to cover the entirety of the sacrificial layer 13, and the lower electrode 15, the piezoelectric film 16 and the upper electrode 17 are stacked in this order on the support layer 14.

Next, as illustrated in FIG. 6(c), the through hole 21 is formed so as to penetrate through the piezoelectric film 16, the lower electrode 15 and the support layer 14 in the thickness directions thereof so as to reach the sacrificial layer 13. Next, as illustrated in FIG. 6(d), the sacrificial layer 13 is removed by introducing an etching liquid from the through hole 21. The second opening 22 is thus formed in the support layer 14.

Next, as illustrated in FIG. 6(e), the first opening 23 is formed by removing material from the substrate 11 by performing dry etching from the rear surface side of the substrate 11 until the second opening 22 is reached. The piezoelectric device of embodiment 2 can be manufactured as described above.

In embodiment 2 as well, the shape and the dimensions of the membrane part can be determined by using the sacrificial layer 13, which has a sufficiently smaller thickness than the substrate 11, and the first opening 23, which has a smaller opening area than the second opening 22, is provided below the second opening 22, and consequently the first opening 23 does not affect the shape and the dimensions of the membrane part, which are determined by the second opening 22, and the volume of the space below the membrane part can be increased. Therefore, in embodiment 2 as well, a piezoelectric device can be provided that can realize excellent characteristics and can reduce variations in the characteristics thereof.

In addition, in embodiment 2, since there is no need to perform a step for forming the insulating layer 12, the amount of work can be reduced. Therefore, the cost of manufacturing the piezoelectric device can be reduced and the piezoelectric device can be efficiently manufactured.

Since the description of the rest of embodiment 2 would be the same as that of embodiment 1, the description is not repeated.

### Embodiment 3

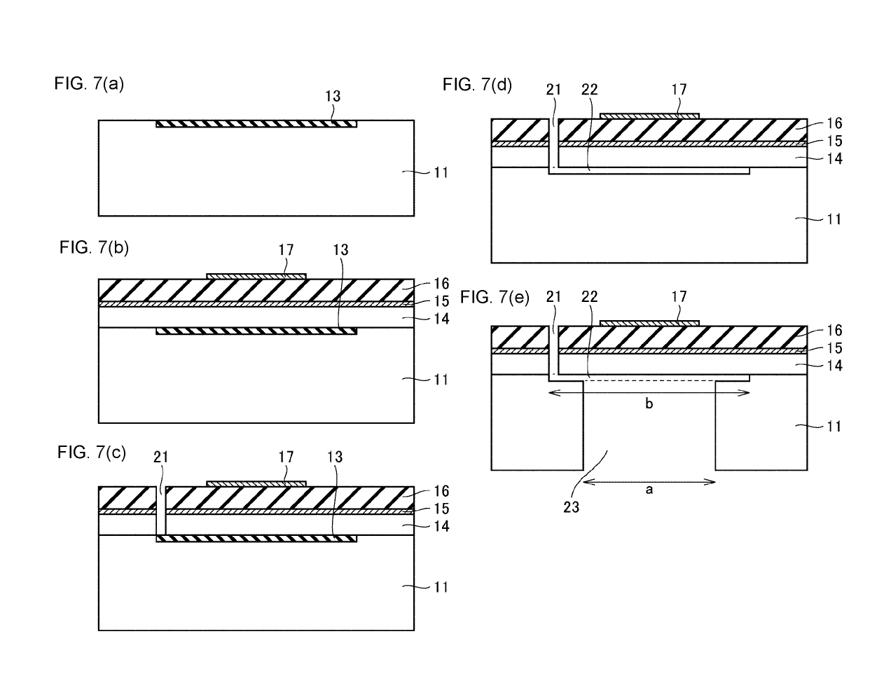

Embodiment 3 is characterized in that a piezoelectric device is manufactured by not forming the insulating layer 12 and by burying the sacrificial layer 13 below the surface of the substrate 11. Hereafter, a method of manufacturing the piezoelectric device of embodiment 3 will be described while referring to the schematic sectional views of FIGS. 7(a) to 7(e).

First, as illustrated in FIG. 7(a), part of the surface of the substrate 11 is removed and the sacrificial layer 13 is formed so as to fill the removed part of the surface of the substrate 11. Here, the method of removing the part of the surface of the substrate 11 is not especially limited and dry etching or wet etching can be used, for example.

Next, as illustrated in FIG. 7(b), the support layer 14 is formed on the substrate 11 so as to cover the entirety of the sacrificial layer 13, and the lower electrode 15, the piezoelectric film 16 and the upper electrode 17 are stacked in this order on the support layer 14.

Next, as illustrated in FIG. 7(c), the through hole 21 is formed so as to penetrate through the piezoelectric film 16, the lower electrode 15 and the support layer 14 in the thickness directions thereof so as to reach the sacrificial layer 13. Next, as illustrated in FIG. 7(d), the sacrificial layer 13 is removed by introducing an etching liquid from the through hole 21. Thus, the second opening 22 is formed in the substrate 11.

Next, as illustrated in FIG. 7(e), the first opening 23 is formed by removing material from the substrate 11 by performing dry etching from the rear surface side of the substrate 11 until reaching the second opening 22. The piezoelectric device of embodiment 3 can be manufactured as described above.

In embodiment 3 as well, the shape and the dimensions of the membrane part can be determined by the sacrificial layer 13, which has a sufficiently smaller thickness than the substrate 11, and the first opening 23, which has a smaller opening area than the second opening 22, is provided below the second opening 22, and consequently the first opening 23 does not affect the shape and the dimensions of the membrane part, which are determined by the second opening 22, and the volume of the space below the membrane part can be increased. Therefore, in embodiment 3 as well, a piezoelectric device can be provided that can realize excellent characteristics and can reduce variations in the characteristics thereof.

Since the description of the rest of embodiment 3 would be the same as that of embodiments 1 and 2, the description is not repeated.

### Embodiment 4

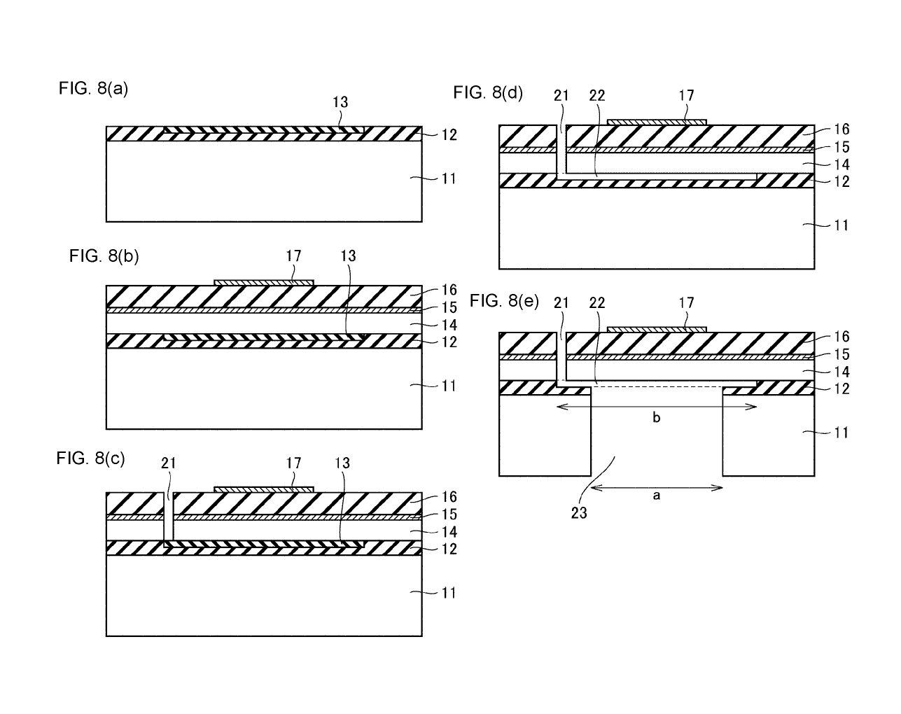

Embodiment 4 is characterized in that a piezoelectric device is manufactured by burying the sacrificial layer 13 below the surface of the insulating layer 12. Hereafter, a method of manufacturing the piezoelectric device of embodiment 4 will be described while referring to the schematic sectional views of FIGS. 8(a) to 8(e).

First, as illustrated in FIG. 8(a), the insulating layer 12 is formed on the substrate 11 and part of the surface of the insulating layer 12 is removed. Then, the sacrificial layer 13 is formed so as to fill the removed part of the surface of the insulating layer 12. Here, the method of removing the part of the surface of the insulating layer 12 is not especially limited and dry etching or wet etching can be used, for example.

Next, as illustrated in FIG. 8(b), the support layer 14 is formed on the substrate 11 so as to cover the entirety of the sacrificial layer 13, and the lower electrode 15, the piezoelectric film 16 and the upper electrode 17 are stacked in this order on the support layer 14.

Next, as illustrated in FIG. 8(c), the through hole 21 is formed so as to penetrate through the piezoelectric film 16, the lower electrode 15 and the support layer 14 in the thickness directions thereof so as to reach the sacrificial layer 13. Next, as illustrated in FIG. 8(d), the sacrificial layer 13 is removed by introducing an etching liquid from the through hole 21. The second opening 22 is thus formed in the insulating layer 12.

Next, as illustrated in FIG. 8(e), the first opening 23 is formed by removing material from the substrate 11 by performing dry etching from the rear surface side of the substrate 11 until reaching the second opening 22. The piezoelectric device of embodiment 4 can be manufactured as described above.

In embodiment 4 as well, the shape and the dimensions of the membrane part can be determined by the sacrificial layer 13 that has a sufficiently smaller thickness than the substrate 11, and the first opening 23, which has a smaller opening area than the second opening 22, is provided below the second opening 22, and consequently the first opening 23 does not affect the shape and the dimensions of the membrane part, which are determined by the second opening 22, and the volume of the space below the membrane part can be increased. Therefore, in embodiment 4 as well, a piezoelectric device can be provided that can realize excellent characteristics and can reduce variations in the characteristics thereof.

Since the description of the rest of embodiment 4 would be the same as that of embodiments 1 to 3, the description is not repeated.

### Embodiment 5

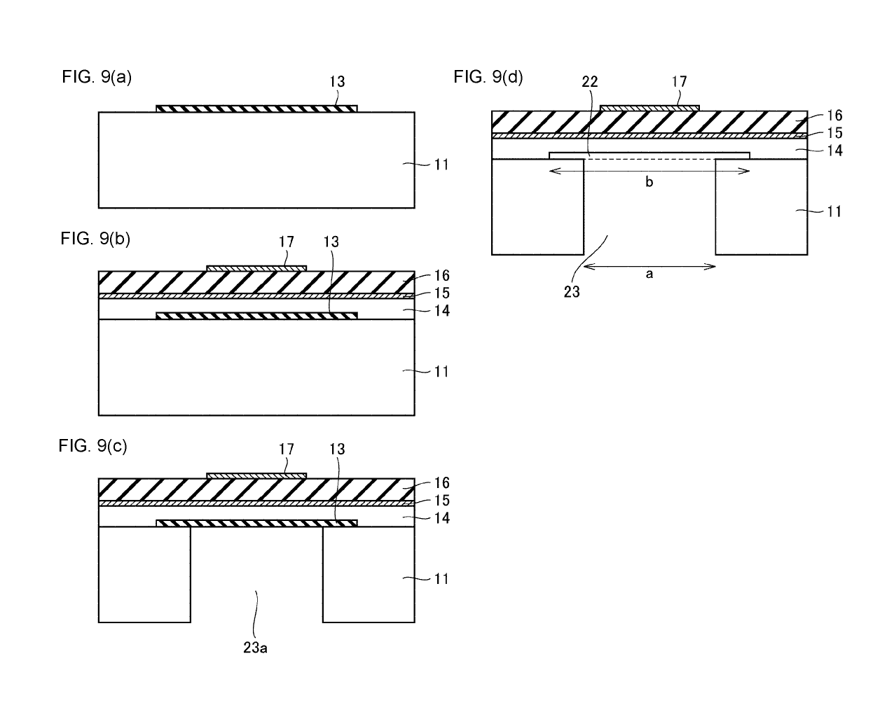

Embodiment 5 is characterized in that a piezoelectric device is manufactured without forming the insulating layer 12 and the through hole 21. Hereafter, a method of manufacturing the piezoelectric device of embodiment 5 will be described while referring to the schematic sectional views of FIGS. 9(a) to 9(d).

First, the sacrificial layer 13 is formed on the substrate 11 as illustrated in FIG. 9(a). Here, it is preferable that a material be used for the sacrificial layer 13 that will enable the sacrificial layer 13 to function as an etching stop layer in etching of the substrate 11, which will be described later. For example, SiO₂, Ti, Al and so forth can be used as the material.

Next, as illustrated in FIG. 9(b), the support layer 14 is formed on the substrate 11 so as to cover the entirety of the sacrificial layer 13, and the lower electrode 15, the piezoelectric film 16 and the upper electrode 17 are stacked in this order on the support layer 14.

Next, as illustrated in FIG. 9(c), the first opening 23 is formed by removing material from the substrate 11 by performing etching from the rear surface side of the substrate 11 until reaching the sacrificial layer 13. Here, the method of etching the substrate 11 is not especially limited, and dry etching or wet etching can be used, for example.

Next, as illustrated in FIG. 9(d), the second opening 22 is formed by etching the sacrificial layer 13 via the first opening 23. The second opening 22 is thus formed in the support layer 14. The piezoelectric device of embodiment 5 is manufactured as described above.

Here, although the method of removing the sacrificial layer 13 is not especially limited, it is preferable that wet etching be used. The sacrificial layer 13 can be removed with high precision when the sacrificial layer 13 is removed using wet etching and therefore variations in the shape and dimensions of the membrane part can be further reduced. Consequently, variations in the characteristics of the piezoelectric device of embodiment 5 can be further suppressed.

In embodiment 5 as well, the shape and the dimensions of the membrane part can be determined by using the sacrificial layer 13, which has a sufficiently smaller thickness than the substrate 11, and the first opening 23, which has a smaller opening area than the second opening 22, is provided below the second opening 22, and consequently the first opening 23 does not affect the shape and the dimensions of the membrane part, which are determined by the second opening 22 and the volume of the space below the membrane part can be increased. Therefore, in embodiment 5 as well, a piezoelectric device can be provided that can realize excellent characteristics and can reduce variations in the characteristics thereof.

In addition, since there is no need to form the through hole 21 in embodiment 5, there are no adverse effects on acoustic characteristics due to sound waves leaking from the through hole 21. Therefore, the characteristics of the piezoelectric device of embodiment 5 are improved compared with the characteristics of the piezoelectric devices of embodiments 1 to 4.

In addition, the piezoelectric device of embodiment 5 can be manufactured with fewer steps than the piezoelectric devices of embodiments 1 to 4. Therefore, the cost of manufacturing the piezoelectric device can be reduced and the piezoelectric device can be efficiently manufactured. In other words, in embodiments 1 to 4, since the sacrificial layer 13 is removed prior to forming the first opening 23, a step for forming the through hole 21 to allow removal of the sacrificial layer 13 is needed. On the other hand, in embodiment 5, since the sacrificial layer 13 is removed after forming the first opening 23, the sacrificial layer 13 can be removed via the first opening 23 and therefore a step for forming the through hole 21 is not needed. In addition, in the piezoelectric devices of embodiments 1 to 4 (particularly in the case of an ultrasonic transducer), sound waves leak from the through hole 21 and the characteristics of the piezoelectric device are degraded. A method of suppressing such degradation of the characteristics by filling in the through hole 21 may be considered, but such a step for filling in the through hole 21 would increase the number of steps involved in manufacturing the piezoelectric device.

Since the description of the rest of embodiment 5 would be the same as that of embodiments 1 to 4, the description is not repeated.

### Embodiment 6

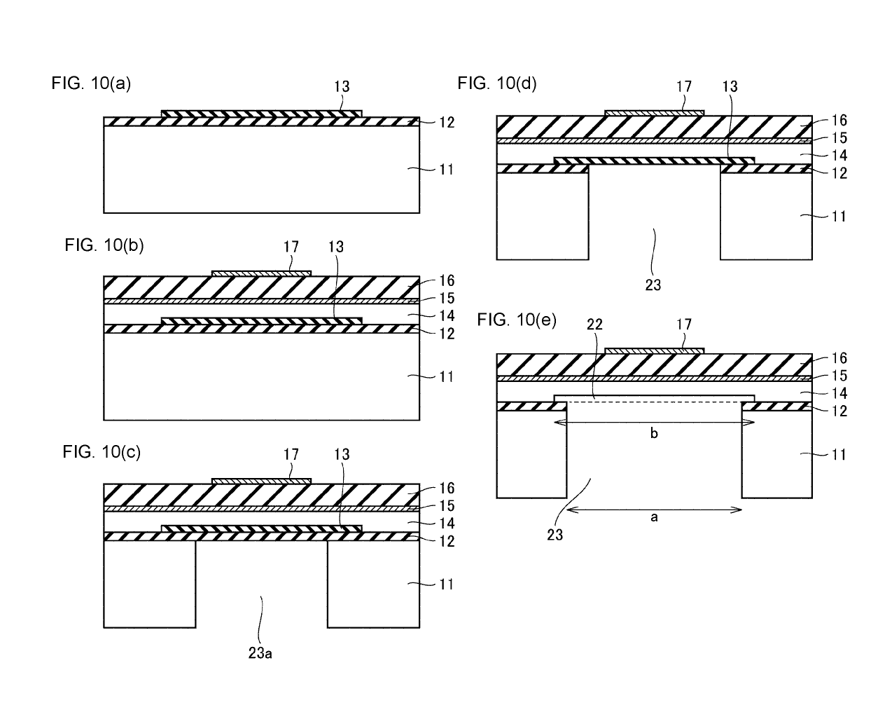

Embodiment 6 is characterized in that a piezoelectric device is manufactured by forming the insulating layer 12, but not forming the through hole 21. Hereafter, a method of manufacturing the piezoelectric device of embodiment 6 will be described while referring to the schematic sectional views of FIGS. 10(a) to 10(e).

First, as illustrated in FIG. 10(a), the insulating layer 12 is formed on the substrate 11 and the sacrificial layer 13 is formed on the insulating layer 12. Next, as illustrated in FIG. 10(b), the support layer 14 is formed on the substrate 11 so as to cover the entirety of the sacrificial layer 13, and the lower electrode 15, the piezoelectric film 16 and the upper electrode 17 are stacked in this order on the support layer 14.

Next, as illustrated in FIG. 10(c), an opening 23a is formed, as a preparatory step for forming the first opening 23, by removing material from the substrate 11 by performing etching from the rear surface side of the substrate 11 until reaching the insulating layer 12.

Next, as illustrated in FIG. 10(d), the surface of the sacrificial layer 13 is exposed by removing the part of the insulating layer 12 that is exposed through the opening 23a, thereby forming the first opening 23.

Next, as illustrated in FIG. 10(e), the second opening 22 is formed by etching the sacrificial layer 13 via the first opening 23. The second opening 22 is thus formed in the support layer 14. The piezoelectric device of embodiment 6 is manufactured as described above.

In embodiment 6 as well, the shape and the dimensions of the membrane part can be determined by using the sacrificial layer 13 that has a sufficiently smaller thickness than the substrate 11, and the first opening 23, which has a smaller opening area than the second opening 22, is provided below the second opening 22, and consequently the first opening 23 does not affect the shape and the dimensions of the membrane part, which are determined by the second opening 22, and the volume of the space below the membrane part can be increased. Therefore, in embodiment 6 as well, a piezoelectric device can be provided that can realize excellent characteristics and can reduce variations in the characteristics thereof.

In addition, since there is no need to form the through hole 21 in embodiment 6 as well, there are no adverse effects on acoustic characteristics due to sound waves leaking from the through hole 21. Therefore, the characteristics of the piezoelectric device of embodiment 6 are also improved compared with the characteristics of the piezoelectric devices of embodiments 1 to 4.

In addition, in embodiment 6 as well, since the sacrificial layer 13 is removed via the first opening 23, there is no need for a step for forming the through hole 21 and therefore the piezoelectric device can be manufactured with fewer steps than in embodiments 1 to 4.

Since the description of the rest of embodiment 6 would be the same as that of embodiments 1 to 5, the description is not repeated.

### Embodiment 7

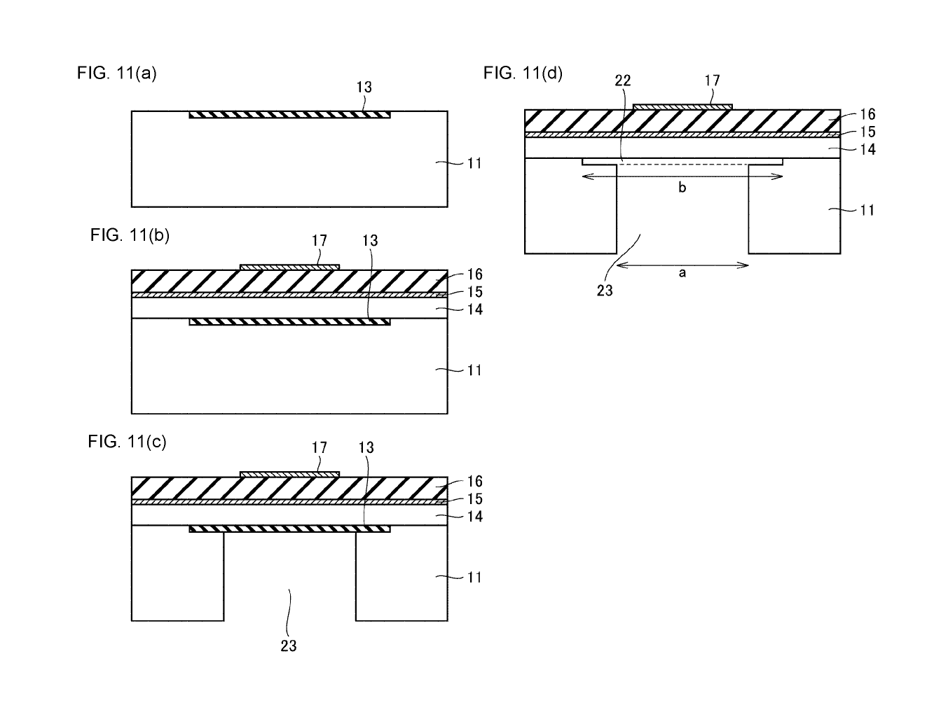

Embodiment 7 is characterized in that a piezoelectric device is manufactured by not forming the insulating layer 12 and the through hole 21 and by burying the sacrificial layer 13 below the surface of the substrate 11. Hereafter, a method of manufacturing the piezoelectric device of embodiment 7 will be described while referring to the schematic sectional views of FIGS. 11(a) to 11(d).

First, as illustrated in FIG. 11(a), part of the surface of the substrate 11 is removed and the sacrificial layer 13 is formed so as to fill the removed part of the surface of the substrate 11.

Next, as illustrated in FIG. 11(b), the support layer 14 is formed on the substrate 11 so as to cover the entirety of the sacrificial layer 13, and the lower electrode 15, the piezoelectric film 16 and the upper electrode 17 are stacked in this order on the support layer 14.

Next, as illustrated in FIG. 11(c), an opening 23a is formed, as a preparatory step for forming the first opening 23, by removing material from the substrate 11 by performing etching from the rear surface side of the substrate 11 until reaching the sacrificial layer 13.

Next, as illustrated in FIG. 11(d), the surface of the support layer 14 is exposed by removing the sacrificial layer 13, which is exposed through the opening 23a, thereby forming the first opening 23. The piezoelectric device of embodiment 7 is manufactured as described above.

In embodiment 7 as well, the shape and the dimensions of the membrane part can be determined by using the sacrificial layer 13, which has a sufficiently smaller thickness than the substrate 11, and the first opening 23, which has a smaller opening area than the second opening 22, is provided below the second opening 22, and consequently the first opening 23 does not affect the shape and the dimensions of the membrane part, which are determined by the second opening 22, and the volume of the space below the membrane part can be increased. Therefore, in embodiment 7 as well, a piezoelectric device can be provided that can realize excellent characteristics and can reduce variations in the characteristics thereof.

In addition, since there is no need to form the through hole 21 in embodiment 7 as well, there are no adverse effects on acoustic characteristics due to sound waves leaking from the through hole 21. Therefore, the characteristics of the piezoelectric device of embodiment 7 are also improved compared with the characteristics of the piezoelectric devices of embodiments 1 to 4.

In addition, in embodiment 7 as well, since the sacrificial layer 13 is removed via the first opening 23, there is no need for a step for forming the through hole 21 and therefore the piezoelectric device can be manufactured with fewer steps than in embodiments 1 to 4.

Since the description of the rest of embodiment 7 would be the same as that of embodiments 1 to 6, description thereof is not repeated.

### Embodiment 8

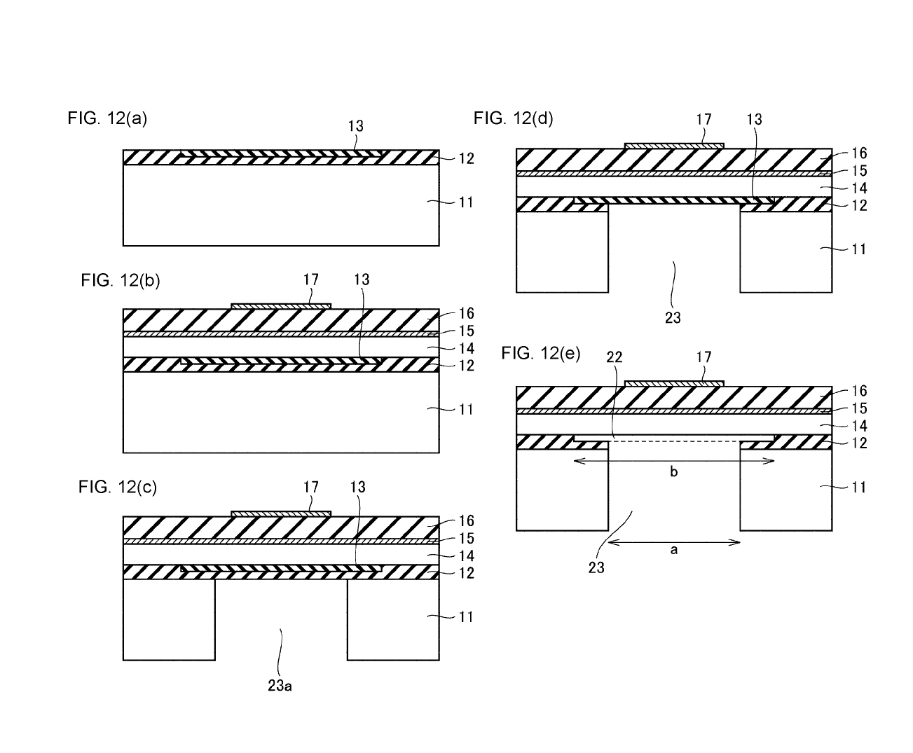

Embodiment 8 is characterized in that a piezoelectric device is manufactured by not forming the through hole 21 and by burying the sacrificial layer 13 below the surface of the insulating layer 12. Hereafter, a method of manufacturing the piezoelectric device of embodiment 8 will be described while referring to the schematic sectional views of FIGS. 12(a) to 12(e).

First, as illustrated in FIG. 12(a), the insulating layer 12 is formed on the substrate 11 and part of the surface of the insulating layer 12 is removed. Then, the sacrificial layer 13 is formed so as to fill the removed part of the surface of the insulating layer 12.

Next, as illustrated in FIG. 12(b), the support layer 14 is formed on the substrate 11 so as to cover the entirety of the sacrificial layer 13, and the lower electrode 15, the piezoelectric film 16 and the upper electrode 17 are stacked in this order on the support layer 14.

Next, as illustrated in FIG. 12(c), an opening 23a is formed, as a preparatory step for forming the first opening 23, by removing material from the substrate 11 by performing etching from the rear surface side of the substrate 11 until reaching the insulating layer 12.

Next, as illustrated in FIG. 12(d), the surface of the sacrificial layer 13 is exposed by removing the part of the insulating layer 12 that is exposed through the opening 23a, thereby forming the first opening 23.

Next, as illustrated in FIG. 12(e), the second opening 22 is formed by etching the sacrificial layer 13 via the first opening 23. The second opening 22 is thus formed in the insulating layer 12. The piezoelectric device of embodiment 8 is manufactured as described above.

In embodiment 8 as well, the shape and the dimensions of the membrane part can be determined by using the sacrificial layer 13, which has a sufficiently smaller thickness than the substrate 11, and the first opening 23, which has a smaller opening area than the second opening 22, is provided below the second opening 22, and consequently the first opening 23 does not affect the shape and the dimensions of the membrane part, which are determined by the second opening 22, and the volume of the space below the membrane part can be increased. Therefore, in embodiment 8 as well, a piezoelectric device can be provided that can realize excellent characteristics and can reduce variations in the characteristics thereof.

In addition, since there is no need to form the through hole 21 in embodiment 8 as well, there are no adverse effects on acoustic characteristics due to sound waves leaking from the through hole 21. Therefore, the characteristics of the piezoelectric device of embodiment 8 are also improved compared with the characteristics of the piezoelectric devices of embodiments 1 to 4.

In addition, in embodiment 8 as well, since the sacrificial layer 13 is removed via the first opening 23, there is no need for a step for forming the through hole 21 and therefore the piezoelectric device can be manufactured with fewer steps than in embodiments 1 to 4.

Since the description of the rest of embodiment 8 would be the same as that of embodiments 1 to 7, the description is not repeated.

Although embodiments and examples of the present invention have been described above, it has always been intended that the configurations of the embodiments and examples described above may be appropriately combined with each other.

The presently disclosed embodiments and examples are illustrative in all points and should be not be considered as limiting. The scope of the present invention is not defined by the above description but rather by the scope of the claims and it is intended that equivalents to the scope of the claims and all modifications within the scope of the claims be included within the scope of the present invention.

A piezoelectric device of the present invention can be suitably used in filters, actuators, sensors, ultrasonic transducers, microphones and so forth, for example.

### REFERENCE SIGNS LIST

11 substrate, 12 insulating layer, 13 sacrificial layer, 14 support layer, 15 lower electrode, 16 piezoelectric film, 17 upper electrode, 21 through hole, 22 second opening, 23 first opening, 23a opening.

1. A piezoelectric device comprising:
a substrate;
a piezoelectric film;
a first electrode and a second electrode, the first and second electrodes sandwiching the piezoelectric film; and
a support layer between the piezoelectric film and the substrate,
wherein the substrate defines a first opening that penetrates through at least part of the substrate in a thickness direction of the substrate,
the piezoelectric device defines a second opening that faces the support layer and is positioned between the first opening and the support layer, and
a first opening area of the first opening is smaller than a second opening area of the second opening.

2. The piezoelectric device according to claim 1, wherein the second opening is positioned so as to contain the first opening in a plan view of the piezoelectric device.

3. The piezoelectric device according to claim 1, wherein the second opening is provided in the substrate.

4. The piezoelectric device according to claim 1, wherein the second opening is provided in the support layer.

5. The piezoelectric device according to claim 1, further comprising:
an insulating layer between the substrate and the support layer.

6. The piezoelectric device according to claim 5, wherein the second opening is provided in the insulating layer.

7. The piezoelectric device according to claim 5, wherein the second opening is provided in the insulating layer and the support layer.

8. The piezoelectric device according to claim 1, wherein the piezoelectric device defines a through hole that penetrates through at least the piezoelectric film and the support layer and extends to the second opening.

9. A method of manufacturing a piezoelectric device, the method comprising:
forming a sacrificial layer at least one of on or below a surface of a substrate;
forming a support layer on the sacrificial layer;
forming a first electrode on the support layer;
forming a piezoelectric film on the lower electrode;
forming an upper electrode on the piezoelectric film;
forming a first opening by removing the sacrificial layer; and
forming a second opening that penetrates through at least part of the substrate in a thickness direction of the substrate by removing at least part of the substrate in the thickness direction of the substrate;
wherein the second opening is formed such that a second opening area of the second opening is smaller than a first opening area of the first opening.

10. The method of manufacturing a piezoelectric device according to claim 9, further comprising:
prior to forming the first opening, forming a through hole that penetrates through at least the piezoelectric film and the lower electrode in thickness directions thereof and extends to the sacrificial layer.

11. The method of manufacturing a piezoelectric device according to claim 10,
wherein the forming the second opening is performed prior to the forming of the first opening, and
forming of the second opening is performed such that a surface of the sacrificial layer is exposed in the second opening.

12. The method of manufacturing the piezoelectric device according to claim 9, further comprising:
prior to the forming of the sacrificial layer, forming an insulating layer on the substrate.

13. The method of manufacturing the piezoelectric device according to claim 12, wherein the sacrificial layer is formed at least one of on or below a surface of the insulating layer.
